(19) United States
(12) Patent Application Publication
(10) Pub. No.: US 2026/0013210 A1
(43) Pub. Date: Jan. 8, 2026

(54) SEMICONDUCTOR DEVICE

(71) Applicant: ROHM CO., LTD., Kyoto (JP)

(72) Inventors: Chikara TERADA, Kyoto (JP); Daisuke ICHIKAWA, Kyoto (JP)

(73) Assignee: ROHM CO., LTD., Kyoto (JP)

(21) Appl. No.: 19/251,317

(22) Filed: Jun. 26, 2025

(30) Foreign Application Priority Data
Jul. 3, 2024 (JP) 2024-107247

(51) Int. Cl. H10D 84/40

(52) U.S. Cl. CPC H10D 84/401

(57) ABSTRACT

A semiconductor device includes a first semiconductor layer of a first conductivity type having a first impurity concentration C₁₁, an epitaxial semiconductor layer disposed on the first semiconductor layer, a first device region formed in a first region of the epitaxial semiconductor layer in a plan view, a second device region formed in a second region of the epitaxial semiconductor layer in a plan view, and to which a higher voltage is applied than a voltage applied to the first device region, and a second semiconductor layer of the first conductivity type having a second impurity concentration C₁₂. The second semiconductor layer is formed on the first semiconductor layer within the first region but is not formed on the first semiconductor layer within the second region. The following relationship is satisfied: C₁₁<C₁₂, and 2×10¹⁴ cm⁻³≤C₁₂≤1×10¹⁶ cm⁻³.

### CROSS REFERENCE TO RELATED APPLICATION

This application is based upon and claims the benefit of priority of the prior Japanese Patent Application No. 2024-107247, filed on Jul. 3, 2024, the entire contents of which are incorporated herein by reference.

### TECHNICAL FIELD

The present disclosure relates to a semiconductor device.

### BACKGROUND ART

U.S. Pat. No. 9,812,565 B2 discloses a semiconductor device including a plurality of types of device regions.

### BRIEF DESCRIPTION OF THE DRAWINGS

FIG. 1A is a plan view of a semiconductor device, and FIG. 1B shows a vertical cross-sectional view along the arrow A-A of FIG. 1A.

FIG. 2 is a vertical cross-sectional view of a first example region in the semiconductor device.

FIG. 3 is a vertical cross-sectional view of a second example region in the semiconductor device.

FIG. 4 is a vertical cross-sectional view of a third example region in the semiconductor device.

FIG. 5 is a vertical cross-sectional view of a fourth example region in the semiconductor device.

FIG. 6A is a vertical cross-sectional view of a first device region 16A, and FIG. 6B is a vertical cross-sectional view of an other device region 16B.

FIG. 7 is a vertical cross-sectional view of a fifth example region in the semiconductor device.

FIG. 8 is a plan view of the fifth example region in the semiconductor device.

FIG. 9 is a vertical cross-sectional view of a sixth example region in the semiconductor device.

FIG. 10 is a chart showing the relationship between an impurity concentration, a leakage current, and a withstand voltage.

FIG. 11A is a graph showing the relationship between the impurity concentration and the leakage current, and FIG. 11B is a graph showing the relationship between the impurity concentration and the withstand voltage.

### DETAILED DESCRIPTION OF EMBODIMENTS

Below, various exemplary embodiments will be described in detail with reference to the drawings. The same or corresponding components in the drawings are assigned the same reference characters and redundant explanations thereof will be omitted.

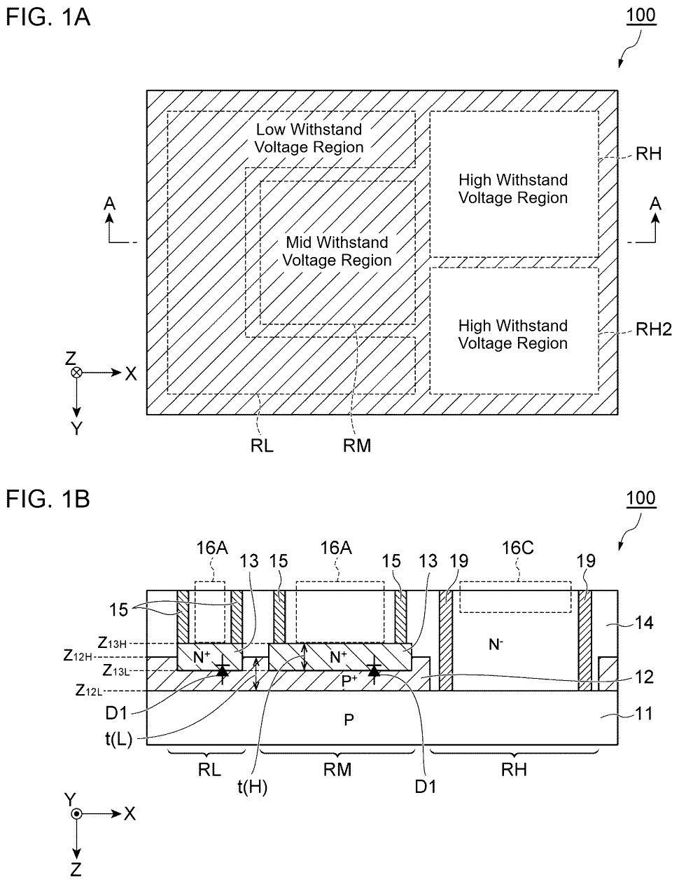

FIG. 1A is a plan view of a semiconductor device, and FIG. 1B shows a vertical cross-sectional view along the arrow A-A of FIG. 1A.

A semiconductor device (semiconductor chip 100) includes a low withstand voltage region RL, a mid withstand voltage region RM, and high withstand voltage regions RH and RH2. In each region, a transistor or the like corresponding to each withstand voltage is disposed. In a bipolar-CMOS-DMOS (BCD) chip, the regions where the double-diffused metal-oxide-semiconductor field effect transistor (DMOS-FET) is formed are the high withstand voltage regions, and the regions where the remaining transistors are formed can be set as the low withstand voltage region RL or the mid withstand voltage region RM. This configuration is an example of a semiconductor chip including a plurality of regions with differing withstand voltages, and semiconductor chips with other configurations are also known. The voltages used to drive the devices in the respective regions differ from each other; devices in the high withstand voltage regions RH and RH2 are provided with a relatively high voltage, devices in the low withstand voltage region RL are provided with a relatively low voltage, and devices in the mid withstand voltage region RM are provided with a voltage intermediate between the foregoing voltages.

The semiconductor device includes a first semiconductor layer 11, and a second semiconductor layer 12 formed on the low withstand voltage region RL and the mid withstand voltage region RM of the first semiconductor layer 11. In other words, the second semiconductor layer 12 is formed in regions excluding the high withstand voltage regions RH and RH2 of the first semiconductor layer 11. The first semiconductor layer 11 is a semiconductor substrate or a semiconductor layer formed on a semiconductor substrate. In order to clarify the region in which the second semiconductor layer 12 is formed, in FIG. 1A, diagonal lines are drawn in the region where the second semiconductor layer 12 is formed.

If setting an XYZ three-dimensional orthogonal coordinate system, the thickness direction (depth direction) of the first semiconductor layer 11 is set to be the Z axis direction. An axis orthogonal to the Z axis is the X axis, and the axis orthogonal to both the Z axis and the X axis is the Y axis. The primary surface of the semiconductor chip 100 in a plan view is the XY plane. With reference to the XZ cross-sectional structure shown in FIG. 1B, an epitaxial semiconductor layer 14 is formed on the first semiconductor layer 11, in the high withstand voltage region RH. The epitaxial semiconductor layer 14 is formed on the second semiconductor layer 12, in the low withstand voltage region RL and the mid withstand voltage region RM. An embedded semiconductor layer 13 is formed on the second semiconductor layer 12. The epitaxial semiconductor layer 14 is positioned on the embedded semiconductor layer 13. The P-type second semiconductor layer 12 and the N-type embedded semiconductor layer 13 are in contact with each other to form a PN junction, and thus, the PN junction can be indicated as a parasitic diode D1. If a voltage exceeding the withstand voltage in the reverse direction of the parasitic diode D1 is applied to the parasitic diode D1, this results in breakdown.

In this example, the first device region 16A is formed on the embedded semiconductor layer 13 in the low withstand voltage region RL. The first device region 16A is also formed on the embedded semiconductor layer 13 in the mid withstand voltage region RM. The first device region 16A is formed on the embedded semiconductor layer 13 and is surrounded by a first isolation region 15 having a loop shape in a plan view. A second device region 16C is formed on the epitaxial semiconductor layer 14 and is surrounded by a second isolation region 19 having a loop shape in a plan view.

The conductivity type of the first semiconductor layer 11 is the P type, and the first semiconductor layer 11 has a first impurity concentration C₁₁. In this example, the P type is designated as a first conductivity type and the N type is designated as a second conductivity type, but the functionality of the element would be maintained even if the conductivity types were reversed. The conductivity type of the epitaxial semiconductor layer 14 is the N type. The first device region 16A is formed in a first region (low withstand voltage region RL or mid withstand voltage region RM) of the epitaxial semiconductor layer 14 in a plan view. The second device region 16C is formed in a second region (high withstand voltage region RH) of the epitaxial semiconductor layer 14 in a plan view. The second device region 16C has applied thereto a voltage higher than the first device region 16A.

The second semiconductor layer 12 is formed on the first semiconductor layer 11 in the first region (low withstand voltage region RL or mid withstand voltage region RM), but is not formed on the first semiconductor layer 11 in the second region (high withstand voltage region RH). The conductivity type of the second semiconductor layer 12 is the P type, and the second semiconductor layer 12 has a second impurity concentration C₁₂. The first impurity concentration C₁₁ and the second impurity concentration C₁₂ satisfy the relationship C₁<C₁₂. The second impurity concentration C₁₂ satisfies the relationship 2×10¹⁴ cm⁻³≤C₁₂≤1×10¹⁶ cm⁻³. With this range, it is possible to suppress leakage current in the low withstand voltage region RL and the mid withstand voltage region RM, while maintaining the withstand voltage. If the impurity concentration of the second semiconductor layer 12 is increased, there is a tendency for the withstand voltage to be reduced. Thus, in the high withstand voltage region RH, the second semiconductor layer 12 not included.

It is preferable that the second impurity concentration C₁₂ satisfy the relationship C₁₂≤6×10¹⁵ cm⁻³. In this case, it is possible to further increase the withstand voltage of the first region (low withstand voltage region RL or mid withstand voltage region RM).

It is preferable that the second impurity concentration C₁₂ satisfy the relationship C₁₂≤4×10¹⁵ cm⁻³. In this case, it is possible to further increase the withstand voltage of the first region (low withstand voltage region RL or mid withstand voltage region RM).

The conductivity type of the embedded semiconductor layer 13 is the N type, and in the first region (low withstand voltage region RL or mid withstand voltage region RM), the embedded semiconductor layer 13 is formed on the second semiconductor layer 12 and has a third impurity concentration C₁₃. The second impurity concentration C₁₂ and the third impurity concentration C₁₃ satisfy the relationship C₁₂<C₁₃. The third impurity concentration C₁₃ satisfies the relationship 1.0×10¹⁸ cm⁻³≤C₁₃≤1.0×10¹⁹ cm⁻³. This is because, if the third impurity concentration C₁₃ falls below the lower limit value, a parasitic NPN bipolar transistor is more susceptible to operating, and if the third impurity concentration C₁₃ exceeds the upper limit value, then the element withstand voltages of the low withstand voltage region and the mid withstand voltage region decrease.

An exemplary value for a thickness t(L) of the second semiconductor layer 12 is 10 μm, and an exemplary value for a thickness t(H) of the embedded semiconductor layer 13 is 6 μm. These values satisfy the relationship of 8 μm≤t(L)≤12 μm, and 5 μm≤t(H)≤7 μm. If the thickness falls below the lower limit value, then the effect of reducing leakage current is weakened, and if the thickness exceeds the upper limit value, then it becomes more difficult to form the element.

An upper end position (Z_{12H}) of the second semiconductor layer 12 is between an upper end position (Z_{13H}) and a lower end position (Z_{13L}) of the embedded semiconductor layer 13. A lower end position (Z_{12L}) of the second semiconductor layer 12 is closer to the first semiconductor layer 11 than the lower end position (Z_{13L}) of the embedded semiconductor layer 13.

The first region (low withstand voltage region RL or mid withstand voltage region RM) includes the first isolation region 15 that surrounds the first device region 16A in a plan view as seen from the Z axis direction, that is of the second conductivity type (N type), and that extends towards the substrate surface from the embedded semiconductor layer 13.

The second region (high withstand voltage region RH) includes the second isolation region 19 that surrounds the second device region 16C in a plan view, that is of the first conductivity type (P type), and that extends towards the substrate surface from the first semiconductor layer 11.

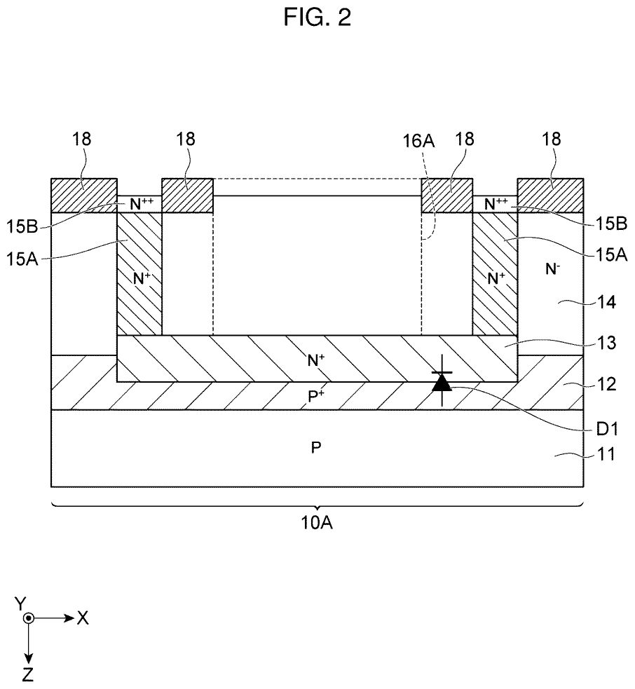

FIG. 2 is a vertical cross-sectional view of a first example region in the semiconductor device.

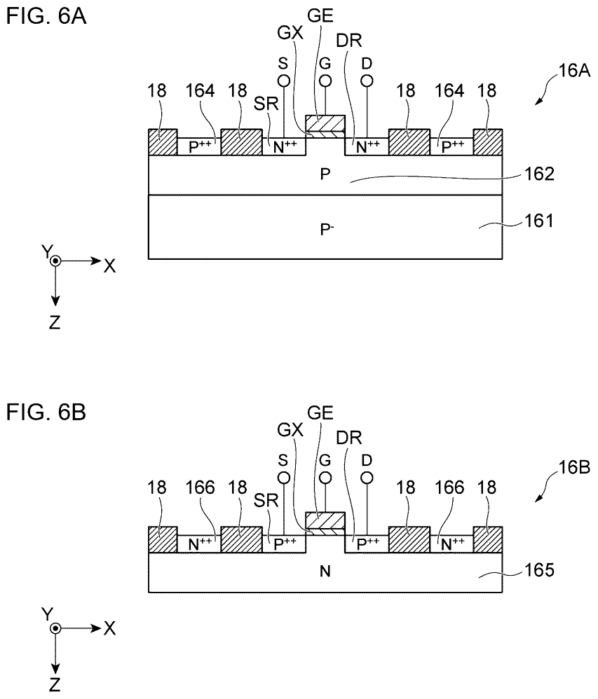

A first example region 10a is an element region in the first region (low withstand voltage region RL or mid withstand voltage region RM). The first device region 16A in the first region includes a first field effect transistor (see FIG. 6A) having a second conductivity-type (N-type) channel, for example. The second semiconductor layer 12 is formed on the first semiconductor layer 11. The embedded semiconductor layer 13 is formed on a portion of the second semiconductor layer 12. A lower first isolation region 15A extends upward from a peripheral region of the embedded semiconductor layer 13. An upper first isolation region 15B is formed on the lower first isolation region 15A. The lower first isolation region 15A and the upper first isolation region 15B constitute the first isolation region 15. The upper first isolation region 15B can be set as a surface contact region that can apply a bias potential as necessary. The conductivity type of both the lower first isolation region 15A and the upper first isolation region 15B is the second conductivity type (N type). The impurity concentration of the upper first isolation region 15B can be set higher than the impurity concentration of the lower first isolation region 15A.

The substrate surface is covered by an insulating region 18. The insulating region 18 is constituted of a field oxide film, a shallow trench isolation (STI) element, or the like.

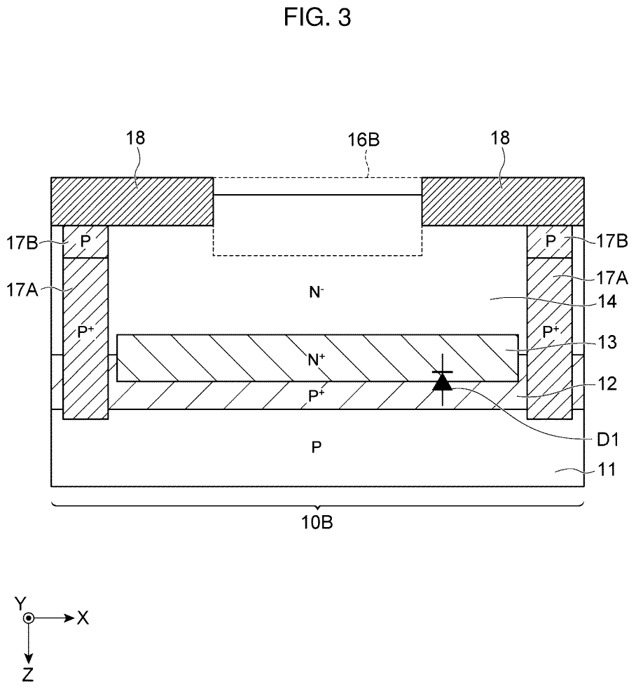

FIG. 3 is a vertical cross-sectional view of a second example region in the semiconductor device.

A second example region 10B is an element region in the first region (low withstand voltage region RL or mid withstand voltage region RM). An other device region 16B differing from the first device region 16A can be provided in the first region. The other device region 16B includes a second field effect transistor (see FIG. 6B) having a first conductivity-type (P-type) channel, for example. The second semiconductor layer 12 is formed on the first semiconductor layer 11. The embedded semiconductor layer 13 is formed on a portion of the second semiconductor layer 12. A lower isolation region 17A extends upward from the first semiconductor layer 11 so as to surround the embedded semiconductor layer 13 in a plan view. An upper isolation region 17B is formed on the lower isolation region 17A. The lower isolation region 17A and the upper isolation region 17B constitute the isolation region 17. The upper isolation region 17B can be set as a surface contact region that can apply a bias potential as necessary, but does not apply a bias potential in this example. The conductivity type of both the lower isolation region 17A and the upper isolation region 17B is the first conductivity type (P type).

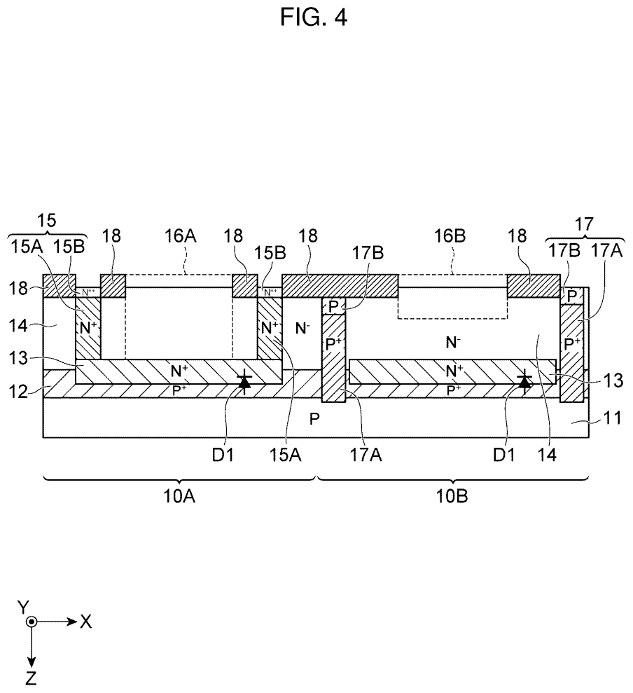

FIG. 4 is a vertical cross-sectional view of a third example region in the semiconductor device.

The third example region is an element region in the first region (low withstand voltage region RL or mid withstand voltage region RM), and has a structure by which the regions 10A and 10B are adjacent to each other.

The first device region 16A formed in the region 10A can be used as the first field effect transistor having the N-type channel. The other device region 16B formed in the region 10B can be used as the second field effect transistor having the P-type channel.

The first device region 16A is surrounded by the N-type first isolation region 15 in a plan view. The first isolation region 15 is connected to periphery of the embedded semiconductor layer 13. The other device region 16B is surrounded by the P-type isolation region 17 in a plan view. The isolation region 17 is connected to the periphery of the first semiconductor layer 11 and extends towards the substrate surface from the first semiconductor layer 11.

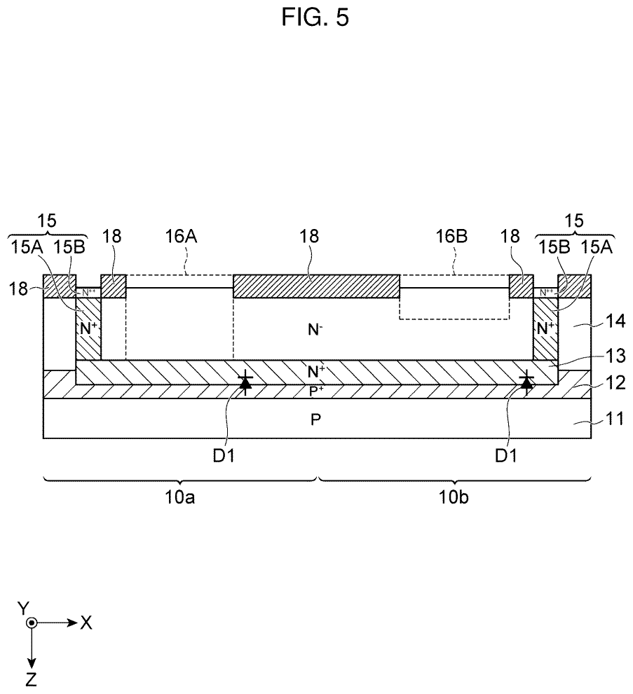

FIG. 5 is a vertical cross-sectional view of a fourth example region in the semiconductor device.

The fourth example region is an element region in the first region (low withstand voltage region RL or mid withstand voltage region RM), and has a structure by which regions 10a and 10b, which result from modifying the isolation region of the regions 10A and 10B, are adjacent to each other.

The first device region 16A formed in the region 10a can be used as the first field effect transistor having the N-type channel. The other device region 16B formed in the region 10b can be used as the second field effect transistor having the P-type channel.

The first device region 16A and the other device region 16B are surrounded by the N-type first isolation region 15 in a plan view. The first isolation region 15 is connected to periphery of the embedded semiconductor layer 13.

FIG. 6A is a vertical cross-sectional view of a first device region 16A, and FIG. 6B is a vertical cross-sectional view of an other device region 16B.

FIG. 6A shows an N-channel-type field effect transistor as the first device region 16A. The first device region 16A includes a first P-type semiconductor layer 161, and a second P-type semiconductor layer 162 formed on the first P-type semiconductor layer 161. An N-type source region SR and an N-type drain region DR are formed on the surface side of the second P-type semiconductor layer 162. A P-type contact region 164 is formed on the surface side of the second P-type semiconductor layer 162. A gate electrode GE is formed on a gate insulating film GX on a region between the source region SR and the drain region DR.

A source terminal S is electrically connected to the source region SR, a drain terminal D is electrically connected to the drain region DR, and a gate terminal G is electrically connected to the gate electrode GE. Areas of the substrate surface where it is not necessary to form electrodes or contacts are covered by the insulating region 18.

The P-type impurity concentration of the first P-type semiconductor layer 161 is lower than the P-type impurity concentration of the second P-type semiconductor layer 162. The P-type impurity concentration of the P-type contact region 164 is higher than the P-type impurity concentration of the second P-type semiconductor layer 162.

FIG. 6B shows a P-channel-type field effect transistor as the other device region 16B. The other device region 16B includes an N-type semiconductor layer 165. A P-type source region SR and a P-type drain region DR are formed on the surface side of the N-type semiconductor layer 165. An N-type contact region 166 is formed on the surface side of the N-type semiconductor layer 165. A gate electrode GE is formed on a gate insulating film GX on a region between the source region SR and the drain region DR.

In the P-channel-type field effect transistor as well, a source terminal S is electrically connected to the source region SR, a drain terminal D is electrically connected to the drain region DR, and a gate terminal G is electrically connected to the gate electrode GE. Areas of the substrate surface where it is not necessary to form electrodes or contacts are covered by the insulating region 18.

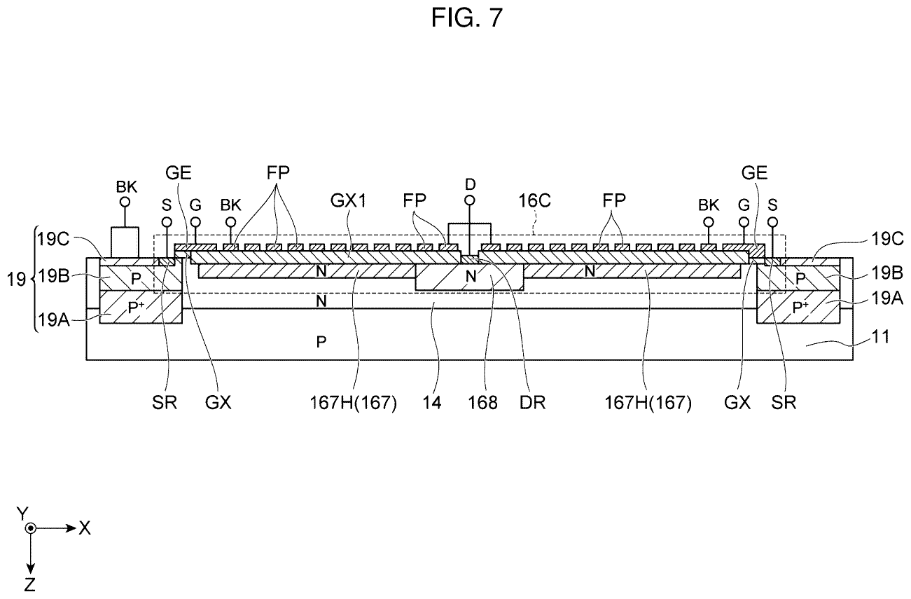

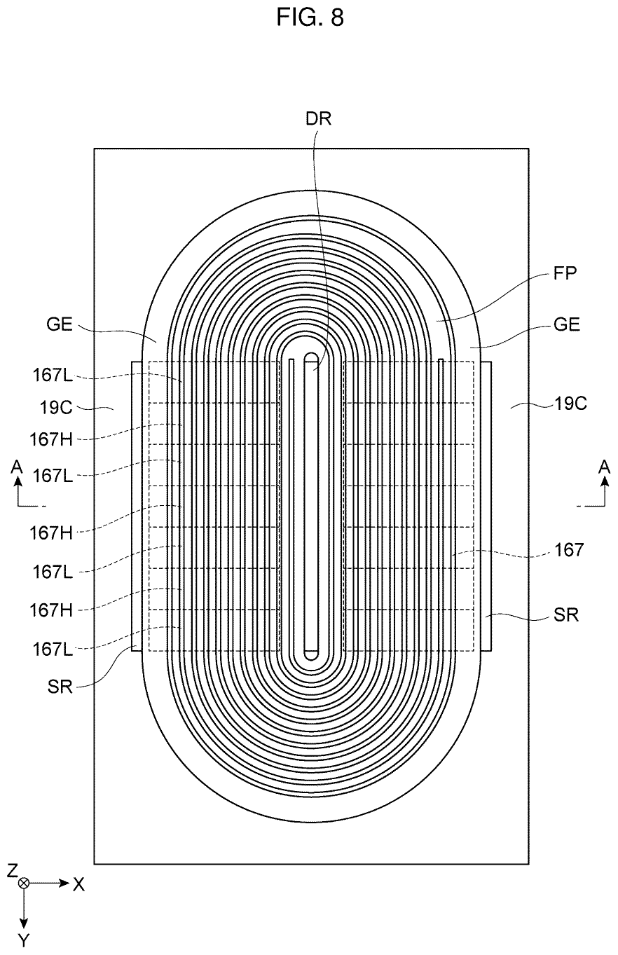

FIG. 7 is a vertical cross-sectional view of a fifth example region in the semiconductor device. FIG. 8 is a plan view of the fifth example region in the semiconductor device. In FIG. 8, an N-type well region 168, terminals, and the like are omitted from the depiction. Also, FIG. 7 shows a vertical cross-sectional configuration along the arrow A-A of FIG. 8.

In this example, an example of a transistor included in the second device region 16C formed in the high withstand voltage region is disclosed. The epitaxial semiconductor layer 14 is formed on the first semiconductor layer 11. In the epitaxial semiconductor layer 14, the second device region 16C including a transistor is formed. The transistor is a field effect transistor.

The field effect transistor formed in the high withstand voltage region (second region) includes a source region SR, a drain region DR, and a drift region 167 interposed between the source region SR and the drain region DR. The drift region 167 is formed on the epitaxial semiconductor layer 14.

The second isolation region 19 is formed so as to surround the device region in a plan view. The second isolation region 19 includes a first P-type semiconductor layer 19A extending upward from the first semiconductor layer 11, a second P-type semiconductor layer 19B (well region) formed above the first P-type semiconductor layer 19A, and a surface contact layer 19C formed on the second P-type semiconductor layer 19B. The first P-type semiconductor layer 19A, the second P-type semiconductor layer 19B, and the surface contact layer 19C all have a conductivity type of P. A ground-level back-gate potential BK is applied to the surface contact layer 19C of the second isolation region 19.

An N-type source region SR is formed in the second P-type semiconductor layer 19B serving as the P-type well region. A portion of the second P-type semiconductor layer 19B is interposed between the source region SR and the epitaxial semiconductor layer 14, and thereon, a gate insulating film GX and a gate electrode GE are formed in the stated order.

An N-type well region 168 is formed in the region between the drift region 167 and the drain region DR, and in the region below the drain region DR. The depth of the N-type well region 168 is greater than the depth of the drift region 167. An insulating film GX1 is formed on the drift region 167 and the N-type well region 168 except in a region directly above the drain region DR. A field plate FP is disposed on the insulating film GX1. The field plate FP is made of a metal material having a spiral shape in a plan view, gradually changes the potential in the X axis direction of the drift region 167, and allows for an increase in withstand voltage.

One end of the field plate FP on the drain side is connected to the drain region DR and the drain terminal D, and has applied thereto a drain potential. One end of the field plate FP on the source side has applied thereto the ground-level back-gate potential BK. If a positive potential is applied to the gate electrode GE via the gate terminal G while applying a source-drain voltage between the source terminal S connected to the source region SR and the drain terminal D connected to the drain region DR, an N-type channel is formed between the source region SR and the drift region 167. The electrons of the source region SR flow through the drift region 167 and arrive at the drain region DR via the N-type well region 168. The structure of this example has a symmetrical structure about the YZ plane passing through the drain region DR. The electrons in the left-side source region SR travel to the right, the electrons in the right-side source region SR travel to the left, and the electrons from both source regions SR arrive at the central drain region DR.

As shown in FIG. 8, the drift region 167 includes first drift regions 167H having a relatively high impurity concentration (C_{167H}) and second drift regions 167L with a relatively low impurity concentration (C_{167L}). The first drift region 167H and the second drift region 167L are arranged alternately along the Y axis direction. In other words, in a plan view, the impurity concentration (C₁₆₇) of the drift region 167 periodically fluctuates along the direction (Y axis direction) orthogonal to the carrier travel direction (X axis direction) in the channel of the field effect transistor. The carrier has a tendency to flow through locations with low resistance. A so-called super junction structure provides the effect of improving characteristics such as by reducing the ON resistance and increasing the withstand voltage, but the effect of improving characteristics of the transistor can also be attained in a stripe structure having variation in impurity concentration as in this example.

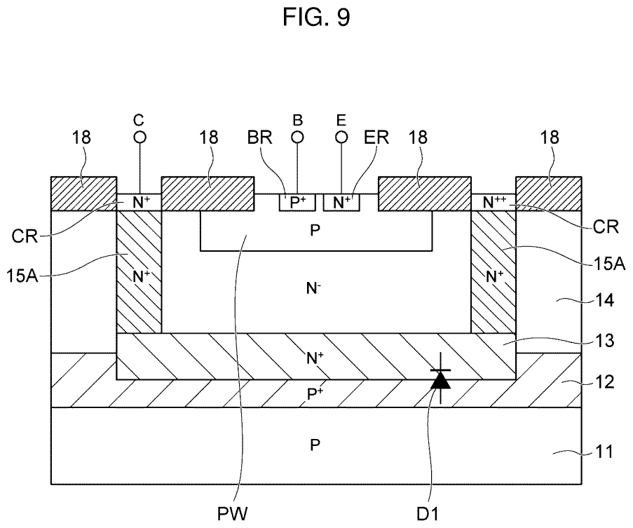

FIG. 9 is a vertical cross-sectional view of a sixth example region in the semiconductor device.

In this example, an example of a transistor included in the first device region 16A formed in the low withstand voltage region or the mid withstand voltage region is disclosed. The transistor of this example is an NPN bipolar transistor. The second semiconductor layer 12 is formed on the first semiconductor layer 11 and the epitaxial semiconductor layer 14 is formed on the second semiconductor layer 12. The embedded semiconductor layer 13 is formed on a portion of the second semiconductor layer 12. The P-type well region PW is formed in the epitaxial semiconductor layer 14 on the embedded semiconductor layer 13. An N-type emitter region ER and a P-type base region BR are formed in the P-type well region PW.

An N-type lower first isolation region 15A extends upward from a peripheral region of the embedded semiconductor layer 13. A collector region CR is formed on the lower first isolation region 15A. The emitter region ER, the base region BR, and the collector region CR are connected to an emitter terminal E, a base terminal B, and a collector terminal C, respectively.

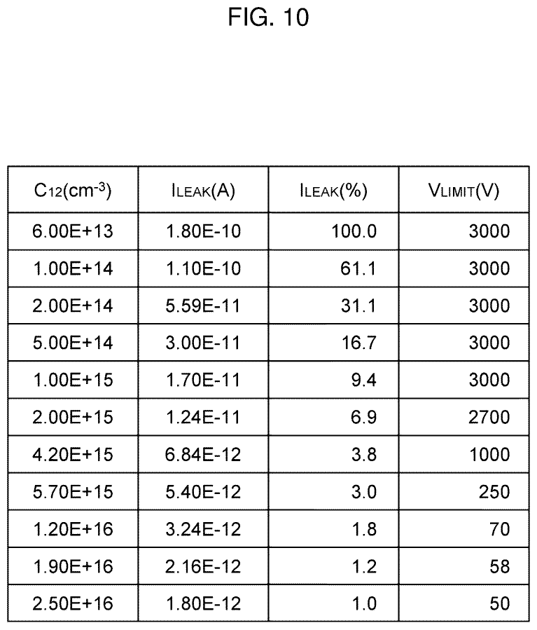

FIG. 10 is a chart showing the relationship between an impurity concentration, a leakage current, and a withstand voltage.

The chart shows, for the structure of the region including the first device region 16A shown in FIG. 1, the second impurity concentration C₁₂(cm⁻³) of the P-type second semiconductor layer 12, a leakage current I_{LEAK}(A) from the first device region 16A towards the first semiconductor layer 11, a leakage current I_{LEAK}(%) normalized such that a reference leakage current (1.8×10⁻¹⁰ A) is 100%, and a withstand voltage V_{LIMIT}(V) yielded by a parasitic diode including the second semiconductor layer 12.

The second impurity concentration C₁₂(cm⁻³) was changed within a range of 6×10¹³ cm⁻³ to 2.5×10¹⁶ cm⁻³. As the second impurity concentration C₁₂(cm⁻³) increases, the leakage current decreases, and thus, the second semiconductor layer 12 functions as a leakage current mitigation layer. On the other hand, if the second impurity concentration C₁₂(cm⁻³) exceeds 1×10¹⁵ cm⁻³, then the withstand voltage V_{LIMIT}(V) starts to rapidly decrease, and at a concentration of 1.2×10¹⁶ cm⁻³, the withstand voltage V_{LIMIT}(V) is reduced to 70V.

From the perspective of slightly suppressing the leakage current, it is preferable that the second impurity concentration C₁₂(cm⁻³) be 1×10¹⁴ cm⁻³, at which the leakage current is reduced to 61.1%. From the perspective of sufficiently suppressing the leakage current, it is preferable that the second impurity concentration C₁₂(cm⁻³) be 2×10¹⁴ cm⁻³, at which the leakage current is reduced to 31.1%. From the perspective that a withstand voltage of approximately 70V is adequate, the second impurity concentration C₁₂(cm⁻³) may be 1.2×10¹⁶ cm⁻³. From the perspective that a withstand voltage of 250V is considerably good, the second impurity concentration C₁₂(cm⁻³) may be 5.7×10¹⁵ cm⁻³.

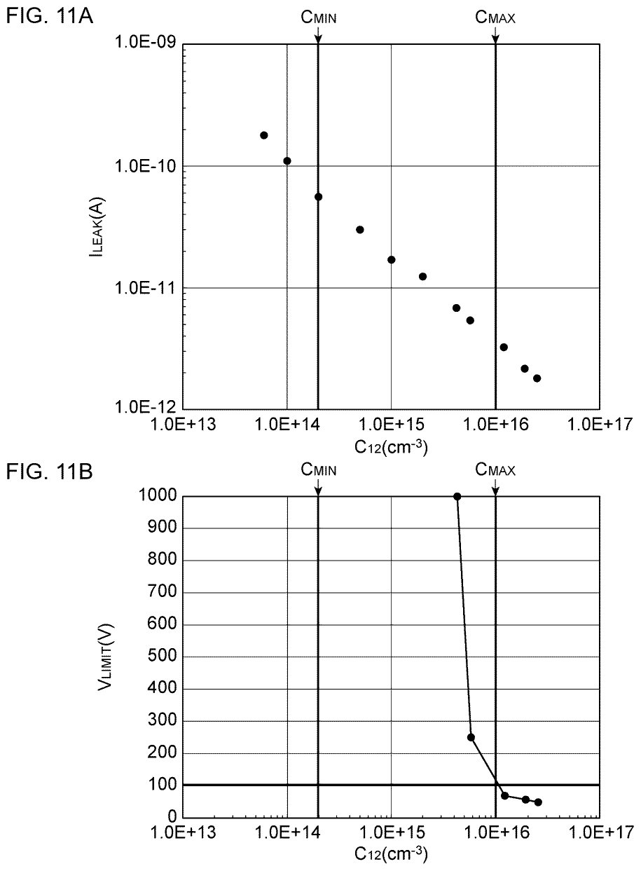

FIG. 11A is a graph showing the relationship between the impurity concentration (C₁₂(cm⁻³)) and the leakage current (I_{LEAK}(A)), and FIG. 11B is a graph showing the relationship between the impurity concentration (C₁₂(cm⁻³)) and the withstand voltage (V_{LIMIT}(V)). The graphs plot the data indicated in FIG. 10.

As the second impurity concentration C₁₂(cm⁻³) increases, the leakage current I_{LEAK} decreases. From the perspective of sufficiently reducing the leakage current, it is preferable that the second impurity concentration C₁₂(cm⁻³) be at C_{MIN} (2×10¹⁴ cm⁻³) or greater. From the perspective of sufficiently maintaining the withstand voltage (100V or greater), it is preferable that the second impurity concentration C₁₂(cm⁻³) be C_{MAX} (1×10¹⁶ cm⁻³) or less.

In order to further increase the withstand voltage, CMAX can also be set to 6×10¹⁵ cm⁻³. That is, C₁₂≤6×10¹⁵ cm⁻³. In this case, the withstand voltage V_{LIMIT}(V) can at least exceed 200V. In order to further increase the withstand voltage, CMAX can also be set to 4×10¹⁵ cm⁻³. That is, C₁₂≤4×10¹⁵ cm⁻³. In this case, the withstand voltage V_{LIMIT}(V) can at least exceed 1,000V.

Next, the materials and impurity concentrations of each of the above-mentioned semiconductor regions will be described.

The semiconductor material constituting the above-mentioned semiconductor chip is silicon (Si). The semiconductor material constituting the semiconductor chip can also be a compound semiconductor. Such compound semiconductors include III-V compound semiconductors, IV-IV compound semiconductors, or mixed crystal semiconductors including the foregoing semiconductors. Ga-containing semiconductors such as GaAs and GaN can be used as the III-V compound semiconductors. Si-containing semiconductors such as SiC and SiGe can be used as the IV-IV compound semiconductors. Impurities can be added to the semiconductor regions through ion implantation or through diffusion.

Specifically, the material of the first semiconductor 11 or the semiconductor substrate includes silicon (Si). The material of the first semiconductor layer 11 can also be made of a compound semiconductor such as silicon carbide (SiC) or gallium nitride (GaN), for example. The conductivity type of the first semiconductor layer 11 is the P type (first conductivity type), and the first impurity concentration (C₁₁) thereof can satisfy 1×10¹⁴ cm⁻³≤C₁₁≤5×10¹⁸ cm⁻³, for example. The thickness for when the first semiconductor layer 11 is the semiconductor substrate is 250 μm to 800 μm, for example.

The material of the second semiconductor layer 12 can be the same as the semiconductor material of the first semiconductor layer 11. The conductivity type of the second semiconductor layer 12 is the P type (first conductivity type), and the second impurity concentration (C₁₂) can satisfy C₁₁<C₁₂. The range of the second impurity concentration C₁₂ and the range of the thickness t(L) of the second semiconductor layer 12 are as described above. The second semiconductor layer 12 can be formed by a method in which a P-type impurity (boron, etc.) is implanted in the first semiconductor layer 11 and thermally diffused, or by implanting a P-type impurity (boron, etc.) into an incomplete epitaxial semiconductor layer 14, and then further growing the epitaxial semiconductor layer 14 thereabove.

The material of the embedded semiconductor layer 13 can be the same as the semiconductor material of the first semiconductor layer 11. The conductivity type of the embedded semiconductor layer 13 is the N type (second conductivity type), and the impurity concentration (C₁₃) can satisfy C₁₁<C₁₃ and C₁₂<C₁₃. The range of the third impurity concentration C₁₃ and the range of the thickness t(H) of the embedded semiconductor layer 13 are as described above. The embedded semiconductor layer 13 can be formed by implanting an N-type impurity (As, etc.) into the second semiconductor layer 12, and then further growing the epitaxial semiconductor layer 14 thereabove.

The material of the epitaxial semiconductor layer 14 can be the same as the semiconductor material of the first semiconductor layer 11. The conductivity type of the epitaxial semiconductor layer 14 is the N type (second conductivity type), and the fourth impurity concentration (C₁₄) can satisfy 5×10¹⁴ cm⁻³≤C₁₄≤1×10¹⁷ cm⁻³, for example. The thickness of the epitaxial semiconductor layer 14 can be set to 3 μm to 20 μm, for example. The impurity concentration of this example satisfies the relationship C₁₄<C₁₁<C₁₃.

It is alternatively possible to set the conductivity type of the epitaxial semiconductor layer 14 to the P type in order to reduce the drain capacitance of the transistor, or the like.

The material of the first P-type semiconductor layer 161 and the second P-type semiconductor layer 162 in the transistor (FIGS. 6A, 6B) can be the same as the semiconductor material of the first semiconductor layer 11. The impurity concentration (C₁₆₁) of the first P-type semiconductor layer 161 can be set lower than the impurity concentration (C₁₆₂) of the second P-type semiconductor layer 162 (C₁₆₁<C₁₆₂). The thickness of such layers can be set to 0.5 μm to 4 μm, for example.

The material of the contact region 164 in the transistor (FIGS. 6A, 6B) can be the same as the semiconductor material of the first semiconductor layer 11. The impurity concentration (C₁₆₄) of the P-type contact region 164 can be set higher than the impurity concentration (C₁₆₂) of the second P-type semiconductor layer 162 (C₁₆₂<C₁₆₄). The thickness of the contact region 164 can be set to 0.2 μm to 1 μm, for example, but a shallower or deeper structure can also be provided therefor.

The material of the source region SR and the drain region DR can be the same as the semiconductor material of the first semiconductor layer 11. The conductivity type of the source region SR and the drain region DR is the N type (second conductivity type), and the respective impurity concentrations (C_{SR}, C_{DR}) can be set to 1×10¹⁹ cm⁻³≤C_{SR}≤5×10²¹ cm⁻³ and 1×10¹⁹ cm⁻³≤C_{DR}≤5×10²¹ cm⁻³ for example. The thickness of the source region SR and the drain region DR can be set to 0.2 μm to 1 μm, for example, but a shallower or deeper structure can also be provided therefor.

The material of the contact region 166 in the transistor (FIGS. 6A, 6B) can be the same as the semiconductor material of the first semiconductor layer 11. The impurity concentration (C₁₆₆) of the N-type contact region 166 can be set higher than the impurity concentration (C₁₆₅) of the N-type semiconductor layer 165 (C₁₆₅<C₁₆₆). The thickness of the contact region 166 can be set to 0.2 μm to 1 μm, for example, but a shallower or deeper structure can also be provided therefor.

The material of the first drift region 167H in the transistor (FIG. 7) can be the same as the semiconductor material of the first semiconductor layer 11. The impurity concentration (C_{167H}) of the N-type first drift region 167H can be set higher than the impurity concentration (C₁₄) of the epitaxial semiconductor layer 14 (C₁₄<C_{167H}). The impurity concentration (C_{167H}) of the first drift region 167H can satisfy 3×10¹⁵ cm⁻³≤C_{167H}≤5×10¹⁷ cm⁻³, for example.

The material of the second drift region 167L in the transistor (FIGS. 7, 8) can be the same as the semiconductor material of the first semiconductor layer 11. The impurity concentration (C_{167L}) of the N-type second drift region 167L can be set to be greater than or equal to the impurity concentration (C₁₄) of the epitaxial semiconductor layer 14 and lower than the impurity concentration (C_{167H}) of the first drift region 167H (C₁₄≤C_{167L}≤C_{167H}). The impurity concentration (C_{167L}) of the second drift region 167L can satisfy 5×10¹⁴ cm⁻³≤C_{167L}≤2×10¹⁶ cm⁻³, for example.

Among the ranges of the various parameters, if the range of a given parameter P is given as Pₘᵢₙ≤P≤Pₘₐₓ, then the following ranges may be set: (Pₘᵢₙ+ΔP)≤P≤(Pₘₐₓ−ΔP), ΔP=(Pₘₐₓ−Pₘᵢₙ)×R %, R=10. Additionally, R may be set to 20, 30, or 40.

Note: As described above, the various embodiments of this disclosure can be defined as follows.

[A1] A semiconductor device, including: a first semiconductor layer 11 of a first conductivity type having a first impurity concentration C₁₁; an epitaxial semiconductor layer 14 disposed on the first semiconductor layer 11; a first device region formed in a first region (e.g., low withstand voltage region RL) of the epitaxial semiconductor layer 14 in a plan view; a second device region formed in a second region (e.g., high withstand voltage region RH) of the epitaxial semiconductor layer 14 in a plan view, and to which a higher voltage is applied than to the first device region; and a second semiconductor layer 12 of the first conductivity type having a second impurity concentration C₁₂, the second semiconductor layer being formed on the first semiconductor layer 11 within the first region (e.g., low withstand voltage region RL) but not being formed on the first semiconductor layer 11 within the second region (e.g., high withstand voltage region RH), wherein the following relationship is satisfied: C₁₁<C₁₂, and 2×10¹⁴ cm⁻³≤C₁₂≤1×10¹⁶ cm⁻³.

[A2] The semiconductor device according to [A1], wherein the following relationship is satisfied: C₁₂≤6×10¹⁵ cm⁻³.

[A3] The semiconductor device according to [A1], wherein the following relationship is satisfied: C₁₂≤4×10¹⁵ cm⁻³.

[A4] The semiconductor device according to [A1], further including: an embedded semiconductor layer 13 of a second conductivity type having a third impurity concentration C₁₃, the embedded semiconductor layer being formed in the second semiconductor layer 12 within the first region (e.g., low withstand voltage region RL),
wherein the following relationship is satisfied: C₁₂<C₁₃.

[A5] The semiconductor device according to [A4], wherein a thickness t(L) of the second semiconductor layer 12 and a thickness t(H) of the embedded semiconductor layer 13 satisfy the following relationship: 8 μm≤t(L)≤12 μm, and 5 μm≤t(H)≤7 μm.

[A6] The semiconductor device according to [A4], wherein an upper end position of the second semiconductor layer is positioned between an upper end position and a lower end position of the embedded semiconductor layer, and wherein a lower end position of the second semiconductor layer is closer to the first semiconductor layer than the lower end position of the embedded semiconductor layer.

[A7] The semiconductor device according to [A4], wherein the first region includes: (low withstand voltage region, mid withstand voltage region) a first field effect transistor (FIGS. 4, 6A) having a channel of the second conductivity type; a first isolation region 15 that surrounds the first field effect transistor in a plan view, that is of the second conductivity type, and that extends from the embedded semiconductor layer 13 towards a substrate surface; a second field effect transistor (FIGS. 4, 6B) having a channel of the first conductivity type; and a second isolation region (17) that surrounds the second field effect transistor in a plan view, that is of the first conductivity type, and that extends from the first semiconductor layer 11 towards the substrate surface.

[A8] The semiconductor device according to [A4], wherein the first region (low withstand voltage region, mid withstand voltage region) includes: a first field effect transistor (FIGS. 5, 6A) having a channel of the second conductivity type; a second field effect transistor (FIGS. 5, 6B) having a channel of the first conductivity type; and an isolation region (15) that surrounds the first field effect transistor (first device region 16A) and the second field effect transistor (other device region 16B) in a plan view, that is of the second conductivity type, and that extends from the embedded semiconductor layer 13 towards a substrate surface.

[A9] The semiconductor device according to [A1], wherein the second region (high withstand voltage region) includes a field effect transistor (FIGS. 7, 8) including: a source region SR; a drain region DR; and a drift region 167 disposed between the source region SR and the drain region DR, wherein the drift region 167 is formed on the epitaxial semiconductor layer 14, and wherein, in a plan view, an impurity concentration (C_{167H}, C_{167L}) of the drift region 167 periodically fluctuates along a direction orthogonal to a carrier travel direction in a channel of the field effect transistor.

The various exemplary embodiments were described above, but the invention is not limited to the exemplary embodiments, and various omissions, substitutions, and modifications may be made. Also, it is possible to combine elements of various embodiments to form another embodiment. Additionally, the various embodiments of this disclosure were described in this specification for the purpose of explanation, and it should be understood that various modifications can be made without departing from the scope and spirit of this disclosure. Thus, the various embodiments disclosed in this specification do not signify limitations to the invention, and the true scope and spirit of the invention is indicated by the attached claims.

What is claimed is:

1. A semiconductor device, comprising:
a first semiconductor layer of a first conductivity type having a first impurity concentration C₁₁;
an epitaxial semiconductor layer disposed on the first semiconductor layer;
a first device region formed in a first region of the epitaxial semiconductor layer in a plan view;
a second device region formed in a second region of the epitaxial semiconductor layer in a plan view, and to which a higher voltage is applied than a voltage applied to the first device region; and
a second semiconductor layer of the first conductivity type having a second impurity concentration C₁₂, the second semiconductor layer being formed on the first semiconductor layer within the first region but not being formed on the first semiconductor layer within the second region,
wherein the following relationship is satisfied:
$$\begin{matrix}{C}_{11} < {C}_{12} , and \\ 2 \times 1 {0}^{14} {cm}^{- 3} \leq {C}_{12} \leq 1 \times 1 {0}^{16} {cm}^{- 3} .\end{matrix}$$

2. The semiconductor device according to claim 1,
wherein the following relationship is satisfied:
C₁₂≤6×10¹⁵ cm⁻³.

3. The semiconductor device according to claim 1,
wherein the following relationship is satisfied:
$${C}_{12} \leq 4 \times 1 {0}^{15} {cm}^{- 3} .$$

4. The semiconductor device according to claim 1, further comprising:
an embedded semiconductor layer of a second conductivity type having a third impurity concentration C₁₃, the embedded semiconductor layer being formed in the second semiconductor layer within the first region,
wherein the following relationship is satisfied:
$${C}_{12} < {C}_{13} .$$

5. The semiconductor device according to claim 4,
wherein a thickness t(L) of the second semiconductor layer and a thickness t(H) of the embedded semiconductor layer satisfy the following relationship:
$$\begin{matrix}8 μ m \leq t ( L ) \leq 12 μ m , and \\ 5 μ m \leq t ( H ) \leq 7 μ m .\end{matrix}$$

6. The semiconductor device according to claim 4,
wherein an upper end position of the second semiconductor layer is positioned between an upper end position and a lower end position of the embedded semiconductor layer, and
wherein a lower end position of the second semiconductor layer is closer to the first semiconductor layer than to the lower end position of the embedded semiconductor layer.

7. The semiconductor device according to claim 4,
wherein the first region includes:
a first field effect transistor having a channel of the second conductivity type;
a first isolation region that surrounds the first field effect transistor in a plan view, that is of the second conductivity type, and that extends from the embedded semiconductor layer towards a substrate surface;
a second field effect transistor having a channel of the first conductivity type; and
a second isolation region that surrounds the second field effect transistor in a plan view, that is of the first conductivity type, and that extends from the first semiconductor layer towards the substrate surface.

8. The semiconductor device according to claim 4,
wherein the first region includes:
a first field effect transistor having a channel of the second conductivity type;
a second field effect transistor having a channel of the first conductivity type; and
an isolation region that surrounds the first field effect transistor and the second field effect transistor in a plan view, that is of the second conductivity type, and that extends from the embedded semiconductor layer towards a substrate surface.

9. The semiconductor device according to claim 1,
wherein the second region includes a field effect transistor including:
a source region;
a drain region; and
a drift region disposed between the source region and the drain region,
wherein the drift region is formed on the epitaxial semiconductor layer, and
wherein, in a plan view, an impurity concentration of the drift region periodically fluctuates along a direction orthogonal to a carrier travel direction in a channel of the field effect transistor.
